(19) United States
(12) Patent Application Publication
(10) Pub. No.: US 2023/0287569 A1
(43) Pub. Date: Sep. 14, 2023

(54) APPARATUS AND METHOD FOR DEPOSITING A LAYER OF SEMICONDUCTOR MATERIAL ON A SUBSTRATE WAFER

(71) Applicant: SILTRONIC AG, Munich (DE)

(72) Inventor: Hannes HECHT, Burghausen (DE)

(73) Assignee: SILTRONIC AG, Munich (DE)

(21) Appl. No.: 18/019,145

(22) PCT Filed: Jul. 16, 2021
(86) PCT No.: PCT/EP2021/070002

§ 371 Date: Feb. 1, 2023

(30) Foreign Application Priority Data
Aug. 14, 2020 (EP) 20191166.6

(51) Int. Cl. C23C 16/458; C30B 25/08; C30B 25/12; C30B 25/14; C23C 16/44; C23C 16/455; H01L 21/3205; H01L 21/02

(52) U.S. Cl. CPC C23C 16/4584; C30B 25/08; C30B 25/12; C30B 25/14; C23C 16/4412; C23C 16/45561; H01L 21/32055; H01L 21/02381; H01L 21/0262; H01L 21/02532; H01L 21/02598

(57) ABSTRACT

An apparatus for depositing a layer of semiconductor material on a substrate wafer. The apparatus includes a base ring between an upper and a lower dome, a susceptor as carrier of the substrate wafer during the deposition of the layer, a gas inlet and a gas outlet, an outgoing gas line and gas supply lines for passing process gas over an upper side face of the substrate wafer, a slit valve tunnel and a slit valve door, and a lifting and rotating unit for lifting and turning the susceptor and the substrate wafer. The apparatus also including an amorphous layer including silicon and hydrogen disposed over one or more stainless steel components of the apparatus.

### CROSS REFERENCE TO RELATED APPLICATIONS

This application is the U.S. National Phase of PCT Application No. PCT/EP2021/070002 filed Jul. 16, 2021, which claims priority to European Application No 20191166.6 filed Aug. 14, 2020, the disclosures of which are incorporated in their entirety by reference herein.

### BACKGROUND OF THE INVENTION

### 1. Field of the Invention

The subject of the invention is an apparatus for depositing a layer of semiconductor material on a substrate wafer by deposition from the vapor phase. A further subject of the invention is a method employing the apparatus.

### 2. Description of the Related Art

Demanding applications in the field of the production of base material for the electronic industry include the deposition of a layer of semiconductor material on a substrate wafer, more particularly the deposition of an epitaxial layer on the substrate wafer.

During the deposition of the layer, the substrate wafer lies at deposition temperature on a susceptor. Process gas is passed over the upper side/face of the substrate wafer, and cleavage products of a chemical compound (precursor) contained in said gas crystallize as a layer of material on the side/face.

Apparatuses such as, for example, the single-wafer reactor described in US 2009 314 205 A1 are particularly suitable for the stated purpose. Said reactor possesses a base ring, which is disposed between an upper and a lower dome. Together they form a reaction chamber which houses a susceptor that carries the substrate wafer during the deposition of the layer of semiconductor material. The substrate wafer is transported into the reaction chamber through a slit valve door and a slit valve tunnel. The process gas is passed by gas supply lines from a gas inlet to a gas outlet. The substrate wafer is brought to deposition temperature by means of thermal radiation.

The base material for the electronics industry must contain very low levels of extraneous substances that can impact the function of electronic components. Such substances include, in particular, metallic impurities. In order to fulfil this requirement even under the prevailing deposition conditions, such as the deposition temperature, apparatus constituents such as the base ring, the gas inlet, the gas outlet, the gas supply lines, the outgoing gas lines (including bellows and cone), the slit valve door, and the slit valve tunnel consist in general of stainless steel.

Although stainless steel is considered to be particularly corrosion-resistant, it is desirable to prevent very largely the possibility of metallic impurities such as iron from the stainless steel from entering the layer of semiconductor material which is deposited on the substrate wafer.

### SUMMARY OF THE INVENTION

An apparatus and method for depositing a layer of semiconductor material on a substrate wafer. The apparatus includes an iron containing components (e.g., stainless steel) such as an upper and lower dome that define a reactor chamber, a base ring disposed between the upper and lower dome, a carrier, a gas inlet, a gas outlet, a gas supply line, an outgoing gas line, a slit valve tunnel, a slit valve door, and a rotating lift. The stainless steel components being coating with a coating including hydrogen and silicon.

### BRIEF DESCRIPTION OF THE DRAWINGS

FIG. 1 shows a number of features of the apparatus with which the invention is concerned, in a sectional representation.

FIG. 2 shows the results of lifetime measurements of minority charge carriers by means of μPCD measurement (microwave photoconductivity decay).

### BRIEF DESCRIPTION OF THE PREFERRED EMBODIMENTS

The problem addressed by the invention is solved by means of an apparatus for depositing a layer of semiconductor material on a substrate wafer, comprising
a base ring between an upper and a lower dome;
a susceptor as a carrier of the substrate wafer during the deposition of the layer;
a gas inlet and a gas outlet, and gas supply lines for passing process gas over an upper side/face of the substrate wafer;
a slit valve tunnel and a slit valve door; and
a lifting and rotating means for lifting and turning the susceptor and the substrate wafer,
wherein one or more apparatus constituents consisting of stainless steel are covered with an amorphous layer which comprises silicon and hydrogen.

It has been found that certain amorphous coatings for stainless steel are particularly suitable for the intended protection of the substrate wafer with deposited layer of semiconductor material with respect to impurities. These are coatings for stainless steel that are themselves generated by means of thermally induced chemical gas vapor deposition and comprise silicon and hydrogen.

At least one apparatus constituent which consists of stainless steel is preferably coated with the coating for stainless steel, at least on a face which is exposed to the process gas during the deposition of the layer of semiconductor material on the substrate wafer. Preferably at least one constituent such as the base ring, the gas inlet, the gas outlet, the gas supply lines, the slit valve door, the slit valve tunnel, and the lifting and rotating unit for lifting and turning a susceptor and the substrate wafer is coated with this coating. It is more preferred if all or virtually all of the apparatus constituents which are made from stainless steel and which come into contact with process gas under the deposition conditions are covered with the coating for stainless steel.

The coating preferably comprises hydrogenated amorphous silicon (a-Si:H) or (a-SiₓC₁₋ₓ:H), more preferably a functionalized silica-like coating (a-SiOₓ:CH_{y}). A hydrogenated amorphous silicon coating on stainless steel is available, for example, under the brand name Silicolloy® from SilcoTek Corp. and under the brand name SilCor® SiC from PT&B SILCOR GmbH, and a functionalized silica-like coating under the brand name Dursan® likewise from SilcoTek Corp. The stainless steel is coated preferably by CVD (chemical vapor deposition) or PCVD (plasma-activated CVD). A method of this kind for placing such a coating on stainless steel is described in EP 2 988 327 A1, for example.

A further subject of the invention is a method for depositing an epitaxial layer of semiconductor material on a substrate wafer, where the substrate wafer is coated with the epitaxial layer in an apparatus having the properties described above.

The substrate wafer is preferably a semiconductor wafer of monocrystalline silicon, on which a layer of monocrystalline silicon is deposited epitaxially under standard pressure. The deposition temperature is preferably 1000° C. to 1300° C. The substrate wafer and/or the epitaxial layer may have been doped with an electrically active dopant. The type of dopant (p-type, n-type) may be the same or different. The substrate wafer preferably has a diameter of at least 200 mm, more preferably of at least 300 mm.

### List of Symbols:

1 upper dome
2 lower dome
3 apparatus
4 substrate wafer
5 susceptor
6 lamps
7 base ring
8 gas inlet for process gas
9 gas inlet for purge gas
10 gas outlet for process gas
11 gas outlet for purge gas
μPCD lifetime values measured by μPCD measurement
N number of measured substrate wafers with deposited epitaxial layer

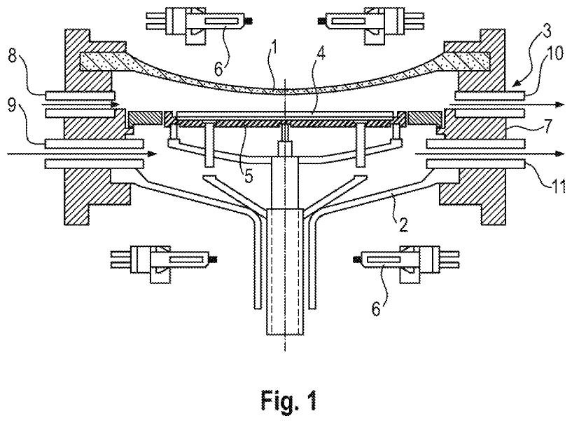

FIG. 1 shows a number of features of the apparatus with which the invention is concerned, in a sectional representation. The apparatus 3 comprises a base ring 7, an upper and a lower dome 1, 2. Disposed above the upper dome 1 and below the lower dome 2 are lamps 6, for heating the substrate wafer to deposition temperature. During the deposition of a layer, the substrate wafer 4 lies on a susceptor 5, which is itself carried by susceptor carrier arms. The susceptor carrier arms are part of a lifting and rotating means for lifting and turning the susceptor and the substrate wafer. Process gas is introduced into the apparatus 3 via gas supply lines and through a gas inlet 8, and passed out of the apparatus through a gas outlet 10. Furthermore, the embodiment shown comprises a further gas inlet 9 and a further gas outlet 11, for passing purge gas through the region below the susceptor during the process of depositing the layer on the substrate wafer.

### Exemplary Embodiment

The exemplary embodiment shows that a useful effect is observable even when the use of coated stainless steel constituents is confined to the use of coated gas supply lines and a coated outgoing gas line. An epitaxial layer of monocrystalline silicon was deposited on monocrystalline silicon substrate wafers having a diameter of 300 mm, in a Epi 300 Centura® apparatus from Applied Materials, Inc. During an experimental series, the faces of the gas supply lines that come into contact with process gas, and the first meter of the outgoing gas line (including bellows and cone), were coated with a layer of Dursan®, whereas a second experimental series were coated with silicon dioxide and, during a third experimental series, uncoated in the original condition with a surface of stainless steel. At the beginning of each experimental series, the apparatus was in the freshly maintained state.

After the deposition of the epitaxial layer, the lifetime of minority charge carriers was determined by means of μPCD on the product wafers.

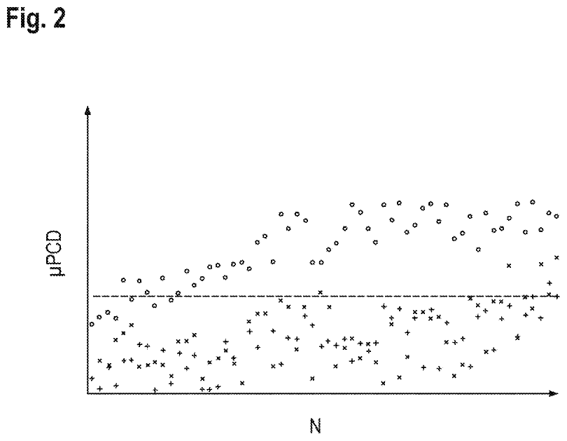

In FIG. 2 the measured μPCD values are plotted against the number N of the measured substrate wafers with a deposited epitaxial layer. In the case of the substrate wafers with epitaxial layer produced in accordance with the invention, longer lifetimes were measured, and an applied threshold value (dashed line) was attained more quickly, suggesting the conclusion that fewer impurities such as iron have been released and taken up in the epitaxial layer.

1.-5. (canceled)

6. An apparatus for depositing a layer of semiconductor material on a substrate wafer comprising:
an upper cover and a lower cover defining a reactor chamber;
a base ring disposed between the upper and lower covers;
a carrier to hold the substrate wafer during the deposition of the layer;
a gas inlet and a gas outlet to pass process gas over an upper side of the substrate wafer;
a slit valve tunnel and a slit valve door; and
a rotating lift to lift and turn the carrier and the substrate wafer,
wherein, one or more components include stainless steel and a coating including silicon and hydrogen is disposed thereon.

7. The apparatus of claim 6, wherein the coating is an amorphous silicon or a functionalized silicon coating thereon.

8. The apparatus of claim 7, wherein the functionalized silicon coating is present and includes a compositions represented by the formula a-SiOₓ:CH_{y}.

9. The apparatus of claim 6, further comprising a gas supply line and outgoing gas line.

10. The apparatus of claim 9, wherein the gas supply line is coated with the coating.

11. The apparatus of claim 10, wherein the outgoing gas line is coated with the coating.

12. The apparatus of claim 6, wherein the one or more components includes one or more of the upper cover, the lower cover, the base ring, the gas inlet, the gas outlet, the gas supply line, the outgoing gas line, the slit valve tunnel, a slit valve door, and the rotating lift.

13. The apparatus of claim 6, wherein the reactor chamber is configured as a single-wafer reactor.

14. The apparatus of claim 6, wherein the upper and lower covers are respectively upper and lower domes.

15. The apparatus of claim 6, wherein the reactor is configured to deposit an epitaxial layer on the substrate wafer.

16. The apparatus of claim 7, wherein the amorphous silicon coating is present.

17. The apparatus of claim 16, wherein the amorphous silicon coating includes a composition represented by the formula a-Si:H.

18. The apparatus of claim 16, wherein the amorphous silicon coating includes a composition represented by the formula a-SiₓC₁₋ₓ:H.

19. The apparatus of claim 6, wherein the substrate wafer has a diameter of at least 200 mm.

20. The apparatus of claim 6, wherein the substrate wafer has a diameter of at least 300 mm.

21. The apparatus of claim 6, wherein the carrier includes a susceptor.

22. The apparatus of claim 6, wherein the coating is applied by chemical vapor deposition.

23. A method for depositing a layer on a substrate wafer, the method comprising:
providing the apparatus of claim 6;
disposing the substrate wafer in the reactor chamber; and
depositing an epitaxial layer of semiconductor material on the substrate wafer.

24. The method of claim 23, wherein the epitaxial layer of semiconductor material is deposited on the substrate wafer at 1000 to 1300° C.

25. The method of claim 23, wherein the substrate wafer and/or the epitaxial layer are doped with an electrically active dopant.
